(19) United States
(12) Patent Application Publication
(10) Pub. No.: US 2025/0125118 A1
(43) Pub. Date: Apr. 17, 2025

(54) DETECTOR DEVICE, ELECTRON BEAM APPARATUS, AND METHOD FOR INSPECTING AND/OR IMAGING A SAMPLE

(71) Applicant: ICT Integrated Circuit Testing Gesellschaft für Halbleiterprüftechnik mbH, Heimstetten (DE)

(72) Inventors: Birgit Schabinger, Poing (DE); Dieter Winkler, München (DE); Eyal Nahum, Jerusalem (IL)

(73) Assignee: ICT Integrated Circuit Testing Gesellschaft für Halbleiterprüftechnik mbH, Heimstetten (DE)

(21) Appl. No.: 18/380,001

(22) Filed: Oct. 13, 2023

(51) Int. Cl. H01J 37/244; H01J 37/14; H01J 37/28

(52) U.S. Cl. CPC H01J 37/244; H01J 37/14; H01J 37/28; H01J 2237/04922; H01J 2237/2007

(57) ABSTRACT

A detector device (10) for detecting signal electrons in an electron beam apparatus (100) is described. The detector device (10) includes an electron detector (120) with a central opening (23) for the passage of a primary electron beam (105) and with one or more radially inner detector segments (21) and one or more radially outer detector segments (22) that at least partially surrounds the central opening. The detector device is configured to amplify one or more first detector signals caused by a first group of signal electrons impinging on the one or more radially inner detector segments (21) with a first amplification strength while amplifying one or more second detector signals caused by a second group of signal electrons impinging on the one or more radially outer detector segments (22) with a second amplification strength higher than the first amplification strength. Further described is an electron beam apparatus with the detector device described herein, as well as a method of imaging and/or inspecting a sample with an electron beam apparatus as described herein.

### TECHNICAL FIELD

Embodiments described herein relate to detector devices for detecting signal electrons, such as secondary electrons (SEs) and backscattered electrons (BSEs), in an electron beam apparatus, e.g., in a scanning electron microscope configured to inspect and/or image a sample. Embodiments described herein particularly relate to electron detectors and to electron beam apparatuses with an electron detector for detecting signal electrons, particularly BSEs. Specifically, electron beam apparatuses for inspecting a sample with 3D-structures by detecting BSEs are described. Embodiments further relate to methods of inspecting and/or imaging a sample with an electron beam apparatus.

### BACKGROUND

Charged particle beam apparatuses have many functions in a plurality of industrial fields including, but not limited to, critical dimensioning of semiconductor devices, defect review of semiconductor devices, inspection of semiconductor devices, exposure systems for lithography, imaging various samples, detecting devices and testing systems. Thus, there is a high demand for structuring, testing and inspecting specimens or samples on the micrometer and nanometer scale.

Micrometer and nanometer scale process control, inspection or structuring is often done with charged particle beams, particularly electron beams, which are generated and focused in charged particle beam devices, such as electron beam apparatuses, particularly electron microscopes. Charged particle beams offer superior spatial resolution compared to, for example, photon beams due to the short wavelengths.

In recent years, it is becoming more and more interesting to inspect and/or image samples with 3D structures or structures having large aspect ratios (such as large ratios of depth to opening width). Devices like 3D FinFETs and 3D NANDs have structures with large aspect ratios which are difficult to image in scanning electron microscopes (SEMs) when using secondary electrons (SEs), i.e. low energy signal electrons generated at the sample surface, when the primary electron beam hits the sample surface. SEs can hardly escape from structures having high aspect ratios and from deeper sample layers and can often not be detected with a reasonable signal to noise ratio. In particular, critical dimension (CD) measurements of high aspect ratio trenches, contact holes and buried layers or structures are a challenge. Image modes which use backscattered electrons (BSEs), i.e. high-energy electrons backscattered from the sample, are often used for increasing the quality of imaging and/or inspection, especially in the semiconductor industry.

In modern charged particle beam inspection systems, it would be beneficial to detect backscattered electrons with a high detection efficiency. This would allow an accurate inspection of both the sample surface extending essentially in an x-y-plane and of 3D-structures having a depth or being buried in the z-direction with a high resolution. In some systems, backscattered electrons which leave the sample at various angles relative to the optical axis are predominantly detected with a detector device arranged close to the sample, e.g., between the objective lens and the sample, or in the vicinity of the objective lens. Secondary electrons (SEs) can be predominantly detected with an electron detector arranged at a larger distance from the sample, e.g. between the beam source and the objective lens in a “through-the-lens detection setup”, or laterally with respect to the optical axis of the system. It is, however, difficult to achieve a high BSE detection efficiency, particularly for high-energy BSEs carrying valuable sample information that may be released from the sample at large angles relative to the optical axis.

In view of the above, it would be beneficial to provide a detector device suitable for efficiently detecting backscattered electrons as well as an electron beam apparatus with such a detector device. Further, it would be beneficial to provide methods for inspecting and/or imaging topographic sample structures or buried sample layers that overcome at least some of the above issues.

### SUMMARY

In light of the above, a detector device, an electron beam apparatus, and methods for inspecting and/or imaging a sample with an electron beam according to the independent claims are provided. Further aspects, advantages, and features are apparent from the dependent claims, the description, and the accompanying drawings.

According to one aspect, a detector device for detecting signal electrons in an electron beam apparatus is provided. The detector device includes an electron detector with a central opening for a passage of a primary electron beam, one or more radially inner detector segments at least partially surrounding the central opening, and one or more radially outer detector segments at least partially surrounding the central opening. The detector device is configured to amplify one or more first detector signals caused by a first group of signal electrons impinging on the one or more radially inner detector segments with a first amplification strength while amplifying one or more second detector signals caused by a second group of signal electrons impinging on the one or more radially outer detector segments with a second amplification strength higher than the first amplification strength.

In some embodiments, the detector device includes the electron detector and an amplifying device that is integrated with the electron detector or arranged adjacent to the electron detector, particularly a pre-amplifier. One or more first amplification circuits of the amplifying device may be connected to the one or more radially inner detector segments, and one or more second amplification circuits of the amplifying device may be connected to the one or more radially outer detector segments. The one or more first amplification circuits are configured to amplify the one or more first detector signals with the first amplification strength, and the one or more second amplification circuits are configured to amplify the one or more second detector signals with the second amplification strength higher than the first amplification strength.

According to another aspect, an electron beam apparatus, particularly a scanning electron microscope, is provided that includes the detector device as described herein.

The electron beam apparatus may include an electron source for generating a primary electron beam propagating along an optical axis, a sample stage for supporting a sample to be inspected, an objective lens for focusing the primary electron beam on the sample for releasing signal electrons, and a detector device as described herein. The detector device is configured to amplify one or more first detector signals caused by a first group of signal electrons impinging on one or more radially inner detector segments with a first amplification strength, while amplifying one or more second detector signals caused by a second group of signal electrons impinging on the one or more radially outer detector segments with a second amplification strength higher than the first amplification strength.

According to another aspect, a method of imaging and/or inspecting a sample is provided, particularly with an electron beam apparatus as described herein.

The method includes generating a primary electron beam propagating along an optical axis; focusing the primary electron beam on the sample for causing an emission of a first group of signal electrons and of a second group of signal electrons, the second group of signal electrons propagating at distances further from the optical axis than the first group of signal electrons. The method further includes amplifying one or more first detector signals caused by the first group of signal electrons impinging on one or more radially inner detector segments of an electron detector with a first amplification strength; and amplifying one or more second detector signals caused by the second group of signal electrons impinging on one or more radially outer detector segments of the electron detector with a second amplification strength higher than the first amplification strength.

Embodiments are also directed at apparatuses for carrying out the disclosed methods and include apparatus parts for performing each described method feature. The method features may be performed by way of hardware components, a computer programmed by appropriate software, by any combination of the two or in any other manner. Furthermore, embodiments are also directed at methods of manufacturing the described apparatuses, methods of using the described apparatuses for inspecting and/or imaging samples, and methods of operating the described apparatuses.

### BRIEF DESCRIPTION OF THE DRAWINGS

So that the manner in which the above recited features of the present disclosure can be understood in detail, a more particular description, briefly summarized above, may be had by reference to embodiments. The accompanying drawings relate to embodiments of the disclosure and are described in the following:

FIG. 1 is a schematic view of an electron beam apparatus with a detector device according to embodiments described herein;

FIG. 2 is a more detailed view of a detector device as described herein;

FIG. 3A shows a detector device with a segmented electron detector as described herein in a schematic perspective view;

FIG. 3B shows the detector device of FIG. 3A in a schematic top view; and

FIG. 4 is a flow chart of a method of imaging and/or inspecting a sample with an electron beam apparatus according to embodiments described herein.

### DETAILED DESCRIPTION OF EMBODIMENTS

Reference will now be made in detail to the various embodiments, one or more examples of which are illustrated in the figures. Within the following description, the same reference numbers refer to the same components. Generally, only the differences with respect to individual embodiments are described. Each example is provided by way of explanation and is not meant as a limitation. Further, features illustrated or described as part of one embodiment can be used on or in conjunction with other embodiments to yield yet a further embodiment. It is intended that the description includes such modifications and variations.

The detector device and the electron beam apparatus described herein are configured for the detection of signal electrons. Signal electrons particularly encompass secondary electrons (SEs) and/or backscattered electrons (BSEs), specifically both secondary and backscattered electrons.

A specimen, sample or wafer as referred to herein includes, but is not limited to, semiconductor wafers, semiconductor workpieces, and other workpieces such as memory disks and the like. A “sample” may specifically be any workpiece that is structured or on which material is deposited. A specimen, a sample or wafer may include a surface that is to be inspected and/or imaged, e.g. a surface that is structured or on which layers or a material pattern have been deposited. For example, a sample may be a substrate or a wafer on which a plurality of electronic devices is provided that are to be inspected. The sample may have several layers, e.g., a stack of layers and/or one or more lower layers buried below one or more upper layers. According to some embodiments, the devices and methods described herein relate to electron beam inspection (EBI), critical dimension measurement and defect review applications, where the devices and methods described herein can be beneficially used to obtain an increased throughput and an improved detection accuracy. According to some embodiments, an electron beam inspection (EBI), critical dimension (CD) measurement tool, and/or defect review (DR) tool can be provided, wherein high resolution, large field of view, and high scanning speed can be achieved.

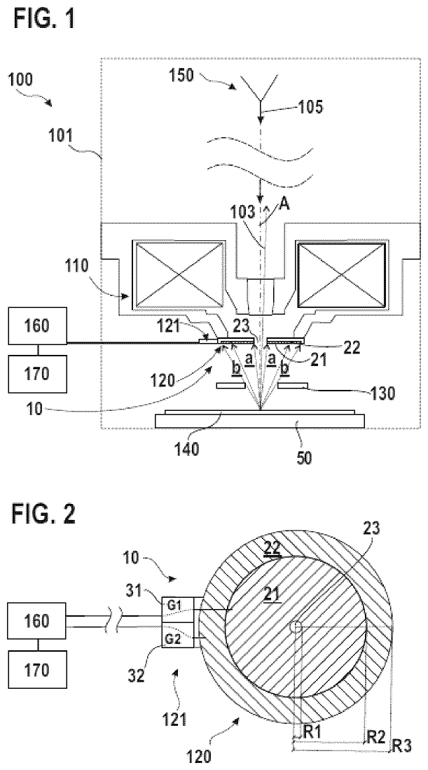

FIG. 1 shows a schematic view of an electron beam apparatus 100 for imaging and/or inspecting a sample 140 according to embodiments described herein. The electron beam apparatus 100 includes a detector device 10 with an electron detector 120 for detecting signal electrons emitted from the sample. FIG. 2 shows the detector device 10 in top view for illustrating further details.

In some embodiments, the electron beam apparatus 100 is a scanning electron microscope (SEM) that includes one or more scan deflectors. The electron beam apparatus 100 includes an electron source 150 for generating a primary electron beam 105 propagating along an optical axis A. The primary electron beam 105 is directed along the optical axis A toward a sample 140 to release signal electrons from the sample upon impingement. The sample 140 may be placed on a sample stage 50, the sample stage 50 including a sample support surface for supporting the sample 140 that extends essentially in an x-y-plane. The sample stage 50 can optionally be movable in the x-y-plane and/or in a z-direction for changing a distance between the sample and the objective lens.

The electron source 150 can, for example, include a cold field emitter (CFE), a Schottky emitter, a thermal field emitter (TFE), or a high current and/or high brightness electron emitter.

The electron beam apparatus 100 can include a plurality of further beam-optical components that are not shown in the figures, such as, but not limited to, one or more condenser lenses, one or more beam deflectors, one or more beam aberration correctors, a beam separator, and/or one or more scan deflectors.

The electron beam apparatus 100 includes an objective lens 110 for focusing the primary electron beam 105 on the sample 140, e.g., a magnetic objective lens, an electrostatic objective lens, or a combined magnetic-electrostatic objective lens.

The primary electron beam 105 travels through a column of the electron beam apparatus 100 before hitting the sample 140 to be imaged and/or inspected. An interior of the column may be evacuated, i.e., the electron beam apparatus typically includes a vacuum chamber 101 such that the primary electron beam propagates through an environment having sub-atmospheric pressure, e.g. a pressure of 1 mbar or less, particularly 1×10⁻⁵ mbar or less, or even 1×10⁻⁸ mbar or less (ultra-high vacuum). The electron source 150 and the objective lens 110 may be arranged inside the vacuum chamber 101 of the electron beam apparatus.

According to some embodiments described herein, the electron beam apparatus 100 is adapted to direct the primary electron beam 105 along the optical axis A to the sample 140 for generating signal electrons. As used herein, signal electrons emitted from a sample can include secondary electrons (SEs) and/or backscattered electrons (BSEs). Secondary electrons are emitted from within a surface of a sample upon impingement of a primary electron beam on the sample. Backscattered electrons are electrons of the primary electron beam which are backscattered from the sample. Backscattered electrons generally have a higher energy compared to secondary electrons. A signal electron beam including BSEs may have a large energy spread and/or a large angular spread when leaving the sample. Backscattered electrons can, for example, have a particle energy above 50 eV, e.g., 1 keV or more, 5 keV or more, 10 keV or more, or even 20 keV or more, and secondary electrons can have a particle energy below 50 eV. “Off-axial” signal electrons are emitted from the sample at an angle relative to the optical axis, e.g., in an angular range from 5° to 90° relative to the optical axis. “Axial” signal electrons are emitted from the sample essentially along the optical axis, e.g., at an angle below 5°.

BSEs are typically reflected from the sample at various angles relative to the optical axis A, and a signal electron beam that includes backscattered electrons can have a considerable angular spread. The signal electron energy and the number of backscattered electrons depend on the landing energy (LE) of the primary electron beam, and a high-energy primary electron beam generally causes a high-energy BSE signal electron beam with a large energy distribution. It depends on the electron energy of the signal electrons (and hence indirectly on the landing energy of the primary electron beam), whether the signal electrons emitted from the sample at large angles relative to the optical axis still impinge on a detector surface of the detector device and can be detected. For example, a low-energy signal electron emitted from the sample at a large angle relative to the optical axis, may still be re-directed onto the detector surface and is, therefore, detectable, while a high-energy signal electron emitted from the sample at a large angle can no longer be detected due to the high electron energy, which makes a re-direction toward the detector more difficult.

As used herein, “a first group of signal electrons” refers to signal electrons propagating in a first range of radial distances from the optical axis in a plane defined by the electron detector so that the first group of signal electrons impinges on radially inner detector segments of the detector device. As used herein, “a second group of signal electrons” refers to signal electrons propagating in a second range of radial distances from the optical axis in the plane defined by the electron detector further away from the optical axis than the first group of signal electrons so that the second group of signal electrons impinges on radially outer detector segments of the detector device. The first group of signal electrons may particularly encompass low- and middle energy signal electrons that are redirected to propagation paths closer to the optical axis as well as higher-energy signal electrons that are emitted at angles comparatively close to the optical axis, such as to impinge on the inner detector segments. The second group of signal electrons may particularly encompass higher-energy signal electrons emitted off-axially from the sample so that the higher-energy signal electrons impinge at a larger distance from the optical axis on the detector device where the radially outer detector segments are located.

The signal electrons of the first group are also referred to herein as “small-angle BSEs” (see reference numeral (a) in FIG. 1), and the signal electrons of the second group are also referred to herein as “large-angle BSEs” (see reference numeral (b) in FIG. 1). In this context “small-angle” and “large-angle” refer to the solid angle/acceptance angle of the electron detector. The signal electrons of the first group can be detected with one or more radially inner detector segments, and the signal electrons of the second group can be detected with one or more radially outer detector segments of the electron detector 120. Specifically, the first group of signal electrons propagates upwards from the sample at distances closer to the optical axis than the second group of signal electrons, such that the first group of signal electrons impinges on the radially inner detector segments, whereas the second group of signal electrons impinges on the radially outer detector segments.

Typically, a high landing energy of the primary electron beam causes a larger number of signal electrons to propagate back from the sample at a larger distance from the optical axis than a low landing energy. For example, if the primary electron beam has a landing energy of 10 keV or less, only a range of 1% to 10% of the signal electrons may impinge on the radially outer segments, because low-energy BSEs—even if reflected from the sample at larger angles—can still be redirected onto a propagation path sufficiently close to the optical axis. If the primary electron beam has a landing energy above 30 keV, the amount of off-axial signal electrons impinging on the radially outer segments may rise to 10% or higher, because high-energy, large-angle BSEs (if still detectable) are typically re-directed onto a propagation path far from the optical axis.

Backscattered electrons can carry valuable information about the topography or geometry of the sample to be inspected, and/or about buried layers or structures below the sample surface. Therefore, a detection of backscattered electrons, including high-energy backscattered electrons released from the sample at high angles with a high detection efficiency, would be beneficial. However, the detection efficiency of off-axial signal electrons released from the sample at large angles relative to the optical axis A may suffer if detected with a conventional electron detector, particularly if using high landing energies of the primary electron beam. One reason is that the typically weak detector signal caused by the off-axial signal electrons emitted at high angles, is not sufficiently taken into account or is lost in the background due to a high signal strength caused by the signal electrons that propagate closer to the optical axis.

According to the embodiments described herein, a detector device 10 is provided that is adapted to also detect the off-axial signal electrons emitted at large angles with a good detection efficiency and/or for improving the signal-to-noise ratio (SNR) of a detector signal caused by the off-axial signal electrons emitted at large angles, even if high landing energies of the primary electron beam are used. In particular, high-energy BSEs emitted from the sample at large angles relative to the optical axis can also be reliably detected, and the signal generated by such “large-angle BSEs” can be analyzed and taken into account during sample testing, sample inspection, sample analysis, or sample imaging.

As is schematically depicted in FIGS. 1 and 2, the detector device 10 includes an electron detector 120 with a segmented detection surface, particularly a segmented semiconductor electron detector, more particularly a segmented PIN diode. The electron detector 120 has a central opening 23, through which the primary electron beam 105 can pass toward the sample through the electron detector 120. The electron detector 120 includes one or more radially inner detector segments 21 that at least partially surround the central opening, e.g., in an annular arrangement, and one or more radially outer detector segments 22 that at least partially surround the central opening, e.g., in an annular arrangement. For example, as is shown in FIG. 2, the one or more radially inner detector segments 21 may surround the central opening 23 in an annular arrangement, and the one or more radially outer detector segments 22 may surround the one or more radially inner detector segments 21 in an annular arrangement.

The terms “radially inner detector segment” and “radially outer detector segment” refer to the radial position of the respective detector segment closer or more distant from the central detector opening (i.e., from the optical axis) in a radial direction. In other words, the “radially inner detector segments” are generally arranged closer to the central opening than the “radially outer detector segments” in a detection plane of the detector. The terms “radially inner” and “radially outer” do not refer to the shape of the respective detector segments. Specifically, the radially inner and/or outer detector segments may have an inner/outer contour having the shape of a circular annulus, as is depicted in the figures, but they can also have other shapes or contours, such as octagonal, polygonal, elliptical etc., as long as the radially outer segments are generally arranged further away from the central detector opening in the radial direction than the radially inner detector segments. Typically, the inner and outer detector segments are provided on one detector body and are arranged in one detection plane that is perpendicular to the optical axis.

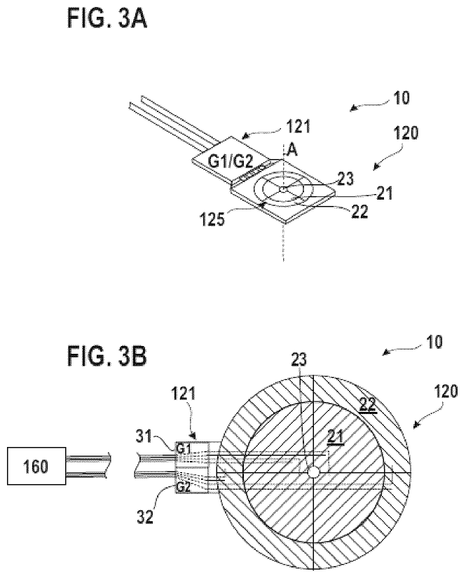

In the exemplary embodiment of FIGS. 1 and 2, the electron detector 120 includes an (annularly shaped) inner detector segment that surrounds the central opening 23, and an (annularly shaped) outer detector segment that surrounds the inner detector segment. It is to be understood that more than one radially inner detector segments and/or more than one radially outer detector segments can be provided, as is schematically depicted in FIGS. 3A and 3B, for improving the topography inspection. Particularly, providing several inner and/or several outer azimuthal detector segments, as in FIGS. 3A and 3B, may enable a more reliable inspection of a sample topography with a high accuracy. For example, a topographic detector may include two, four, or eight radially inner detector segments and two, four or eight radially outer detector segments, e.g., in a four-quadrant configuration.

Returning to FIGS. 1 and 2, the detector device 10 is configured to amplify one or more first detector signals caused by the first group of signal electrons impinging on the one or more radially inner detector segments 21 with a first amplification strength (G1 for “first gain” or “first amplification factor”) and to amplify one or more second detector signals caused by the second group of signal electrons impinging on the one or more radially outer detector segments 22 with a second amplification factor (G2 for “second gain” or “second amplification factor”) higher than the first amplification strength. Thereby, large-angle BSEs generate a higher detector output signal per BSE than small-angle BSEs. For example, the second amplification strength G2 may be higher than the first amplification strength G1 by a factor of two or more, three or more, four or more, or even five or more.

An “amplification strength” as used herein relates to an output signal strength provided by the detector device 10 per current or per number of signal electrons hitting a detection surface of the electron detector. Specifically, the detector device may provide an output signal (in [V]) that depends on the number of signal electrons (in ampere [A]) hitting a detection surface of the electron detector (namely, a large number of signal electrons causes a high output signal of the detector device, and a small number of signal electrons causes a small output signal of the detector device). If the “amplification strength” of a detector segment is high, the detector device provides a high output signal per signal electron impinging on the detector segment.

Accordingly, the second amplification strength G2 being higher than the first amplification strength G1 means that the detector device provides a higher output signal (e.g., in [V]) per signal electron impinging on the one or more radially outer detector segments 22 than per signal electron impinging on the one or more radially inner detector segments 21. In one example, the first amplification strength G1 (=the first gain) may be from 30 kV/A to 60 kV/A for the one or more first detector signals caused by the first group of signal electrons impinging on the radially inner detector segments. In other words, 1 Ampere of signal electrons impinging on an inner segment would cause an output signal of the detector device for the respective inner segment in a range between 30 kV and 60 kV. The second amplification strength G2 (=the second gain) may be from 200 kV/A to 300 kV/A for the one or more second detector signals caused by the second group of signal electron impinging on the radially outer detector segments. In other words, 1 Ampere of signal electrons impinging on an outer segment would cause an output signal of the detector device for the respective outer segment between 200 kV and 300 kV.

In some embodiments, which can be combined with other embodiments described herein, the detector device 10 includes the electron detector 120 and an amplifying device 121, particularly a pre-amplifier. The amplifying device 121 is connected to the one or more radially inner detector segments 21 and to the one or more radially outer detector segments 22. The amplifying device 121 may be configured to amplify the one or more first detector signals provided by the one or more radially inner detector segments and caused by the first group of signal electrons with the first amplification strength G1, and to amplify the one or more second detector signals provided by the one or more radially outer detector segments and caused by the second group of signal electrons with the second amplification strength G2. The second amplification strength G2 is higher than the first amplification strength G1. Thereby, large-angle signal electrons propagating far from the optical axis cause a higher detector output signal than small-angle signal electrons propagating closer to the optical axis.

The amplifying device 121 may include one or more first amplification circuits 31 connected to the one or more radially inner detector segments and providing the first amplification strength G1 (in particular, one amplification circuit connected to each of the inner detector segments). The amplifying device 121 may include one or more second amplification circuits 32 connected to the one or more radially outer detector segments and providing the second amplification strength G2 (in particular, one amplification circuit connected to each of the outer detector segments).

As is schematically illustrated in FIG. 2, the one or more radially inner detector segments 21 may provide one or more first detector signals (e.g., in Amperes [A]) that are respectively amplified by the one or more first amplification circuits 31 with the first amplification strength G1 to provide one or more first detector output signals (e.g., in voltage [V]). The first amplification strength G1 may, for example, be 30 kV/A or more and 60 kV/A or less. The one or more radially outer detector segments 22 provide one or more second detector signals (e.g., in Amperes [A]) that are respectively amplified by the one or more second amplification circuits 32 with the second amplification strength G2 to provide one or more second detector output signals (e.g., in voltage [V]). The second amplification strength G2 may, for example, be 200 kV/A or more and 300 kV/A or less.

The first group of signal electrons impinging on the one or more radially inner detector segments 21 causes the generation of one or more first detector signals (one first detector signal per inner segment), and the one or more first detector signals may be amplified with the one or more first amplification circuits 31 of the amplifying device 121 with the first amplification strength G1. The second group of signal electrons impinging on the one or more radially outer detector segments 22 causes the generation of one or more second detector signals (one second detector signal per outer segment), and the one or more second detector signals may be amplified by the one or more second amplification circuits 32 of the amplifying device 121 with the second amplification strength G2.

Accordingly, the second group of signal electrons that includes large-angle BSEs generates the one or more second detector signals that are more strongly amplified than the one or more first detector signals that are generated by the first group of signal electrons (including small-angle BSEs). A reliable detection of large-angle BSEs is generally challenging, particularly if the large-angle BSEs have a high electron energy (e.g., if the landing energy of the primary electron beam is high). By amplifying the detector signals caused by the large-angle BSEs with a higher amplification strength, the contribution of the large-angle BSEs to the sample inspection and image generation can be increased, and/or the signal-to-noise ratio of the (typically small) portion of the output signal of the detector that is caused by the large-angle signal electrons can be improved. The valuable information provided by large-angle signal electrons, particularly by large-angle BSEs having high electron energies, is more reliably retrieved, enabling a more accurate 3D-imaging and inspection of complex sample topographies and/or buried layer topographies.

In some implementations, the one or more first amplification circuits 31 apply the first amplification strength G1 while—at the same time—the one or more second amplification circuits 32 apply the second amplification strength G2 on the respective detector signals. Therefore, one beam of signal electrons emitted from the sample causes different detector signals that are (simultaneously) amplified with different amplification strengths, depending on whether a signal electron belongs to the first group and impinges on an inner detector segment or to the second group and impinges on an outer detector segment.

In some implementations, the one or more first amplification circuits 31 and/or the one or more second amplification circuits 32 are transimpedance amplification circuits (TIAs) or belong to one or more transimpedance amplification circuits. For example, the one or more first amplification circuits 31 connected to the one or more radially inner detector segments 21 include one or more first TIAs characterized by a first current-to-voltage gain, and particularly characterized by a first feedback resistance. The one or more second amplification circuits 32 connected to the one or more radially outer detector segments 22 can include one or more second TIAs characterized by a second current-to-voltage gain larger than the first current-to-voltage gain, and particularly characterized by a second feedback resistance different from the first feedback resistance.

In some embodiments, the first amplification strength G1 and the second amplification strength G2 are invariable. In particular, the amplifying device 121 may have fixed amplification strengths (the first and the second amplification strengths G1, G2) that cannot be modified or varied. Specifically, the first amplification circuit and the second amplification circuit 32 may be respectively configured for a fixed amplification strength that may be defined by one or more respective resistors. Amplifiers with variable amplification gains are typically slower than fixed-gain amplifiers, such that the obtainable detection speed and the signal-to-noise ratio would be negatively affected by providing a variable-gain amplification within the detector device 10.

It is, however, to be noted that an (optional) main amplifier 160 configured to further amplify the pre-amplified signals provided by the amplifying device 121 can (optionally) provide a variable amplification strength. Once pre-amplified within the detector device 10 by a pre-amplifier, particularly directly after the signal electron detection and preferably without a signal transport over a distance from the detector surface, the signals are more robust and can be transported out of the vacuum chamber 101 for being further amplified and/or processed, e.g. by a main amplifier 160 and/or a signal evaluation module 170. The main amplifier 160 can optionally have a variable gain. Different from the (optional) main amplifier 160 that is considered as a separate component, the amplifying device 121 described herein is a part of the detector device 10 that is integrated with or arranged close to the electron detector.

In some embodiments, which can be combined with other embodiments described herein, the second amplification strength G2 is higher than the first amplification strength G1 by a factor or 2 or more, particularly 5 or more.

Accordingly, a signal electron impinging on a radially outer detector segment causes as detector output signal that has at least twice the amplitude of a detector output signal caused by a signal electron impinging on a radially inner detector segment.

In some embodiments, which can be combined with other embodiments described herein, the detector device is a segmented in-lens detector, particularly a segmented in-lens BSE detector. In particular, the detector device may be arranged in the vicinity of the objective lens, e.g., close to a magnetic lens gap of a magnetic objective lens, or arranged between the objective lens and the sample stage. The detector device may, for example, be mounted at a position directly downstream of the objective lens in the propagation direction of the primary electron beam. A location of the detector device close to the sample stage increases the angular range of signal electrons that can be “caught” by the electron detector. In particular, high-energy signal electrons emitted by the sample at angles larger than, e.g., 45° or even larger than 65° can hit a detection surface (at a radially outer detector segment) of the electron detector and can be detected.

In some embodiments, the central opening 23 may be round or circular and may be partially or completely surrounded by the one or more radially inner detector segments 21. For example, the central opening 23 may have a first radius (R1) of 500 μm or more, particularly 1 mm or more, and/or 3 mm or less. The primary electron beam (with a typical beam diameter below 500 μm) can propagate through the central opening 23 toward the sample without being negatively affected by the electron detector. Optionally, axial signal electrons 103 and/or signal electrons emitted from the sample close to the optical axis can propagate through the central opening in a direction opposite to the propagation direction of the primary electron beam 105. An optional second electron detector (not shown in FIG. 1) can be located downstream of the objective lens in the propagation direction of the signal electrons. Axial signal electrons, particularly SEs, can be detected, for example, in a “through-the-lens” detection setup with one or more optional secondary electron detectors.

In some embodiments, which can be combined with other embodiments described herein, the detector device 10 includes the electron detector 120 and the amplifying device 121, particularly a pre-amplifier, wherein the amplifying device 121 is connected to the electron detector 120, particularly integrated with the electron detector 120 or arranged directly adjacent to the electron detector 120. For example, the electron detector and the pre-amplifier may be integrated in the same detector housing, provided on a common support and/or within the same chip or circuit board.

In some implementations, the amplifying device 121 is at least one of (i) integrated with the electron detector, (ii) arranged directly adjacent to the electron detector 120 inside the vacuum chamber 101 of the electron beam apparatus, and/or (iii) fixedly mounted in the vacuum chamber 101 of the electron beam apparatus. Specifically, the detector device 10 may include the electron detector 120 and the amplifying device 121 (which may be a pre-amplifier) integrated with each other to provide one compact and integrated detector device that can be placed, for example, close to the objective lens inside the vacuum chamber. A small transport distance of the detector signals between the electron detector and the pre-amplifier improves the signal integrity and the signal-to-noise ratio, particularly if large amplification strengths are used for the outer detector segments. For example, small detector signals caused by BSEs propagating distant from the optical axis can be directly amplified after the signal generation, which improves the signal quality.

In an arrangement of the amplifying device 121 “adjacent to” the electron detector 120, a distance between a detection surface of the electron detector and the amplifying device may be 5 cm or less, particularly 3 cm or less, more particularly 2 cm or less. Both the amplifying device and the electron detector may be provided in a vacuum chamber of the electron beam apparatus, e.g. inside the column or close to an end of the column. Fixedly mounting the amplifying device at a position close to the electron detector may be understood as an essentially immovable positioning of the amplifying device at a position close to the electron detector and is meant to distinguish from other solutions in which a detector device can be pivoted or otherwise moved toward and away from a detection position close to the sample in a sample chamber, i.e. outside of the column.

In some embodiments, the detector device 10 includes a support, e.g. a plate or housing, on which the electron detector 120 and the amplifying device 121 are both mounted. The support may be arranged adjacent to a downstream end of the column of the electron beam apparatus, e.g. fixed at the objective lens 110. Specifically, the electron detector 120 and the amplifying device 121 may be provided as one integrated detector module, including the amplifying device integrated with the electron detector on the common support of the detector device 10 or even on a single chip. In some embodiments, a detector device 10 includes a common support, supporting both the electron detector 120 and the amplifying device 121 at a close distance (of, e.g., 3 cm or less).

Arranging the amplifying device close to the electron detector, particularly inside the vacuum housing of the electron beam apparatus (e.g., inside or close to the column), and/or integrating the amplifying device 121 and the electron detector 120 to provide an integrated detector module is beneficial because the detection speed and the detection efficiency can be increased. Fixed mounting of the amplifying device at a position close to the electron detector improves the signal-to-noise ratio and improves the detection efficiency and the maximum detection speed. For example, increased signal intensities can be achieved by mounting the amplifying device 121 at a position close to the electron detector 120. This may enable fast imaging/detection speeds with high scan rates of, e.g., 10 MHz or faster, or 20 MHz or faster.

In some embodiments, the amplifying device 121 may be an electronic amplifier, particularly an operational amplifier. In some embodiments, the electron detector 120 may be a solid-state or semiconductor detector, particularly including a PIN diode. The electron detector 120 may provide an electric signal (e.g., a current signal) that is pre-amplified by the amplifying device 121, e.g., to provide a voltage signal. The amplifying device may include TIAs. The pre-amplified signal from the amplifying device 121 may then be forwarded to the signal evaluation module 170.

In some implementations, a main amplifier 160 may be provided in addition to the amplifying device 121. The amplifying device 121 may be a pre-amplifier arranged in a vacuum chamber of the electron beam apparatus, particularly integrated with or in close vicinity to the electron detector, and the pre-amplified signal provided by the pre-amplifier can be further amplified by the main amplifier 160 that can be arranged outside of the vacuum chamber of the electron beam apparatus. The main amplifier 160 can forward the amplified signal to the signal evaluation module 170. The main amplifier 160 can optionally have a variable gain. The main amplifier 160 is considered as a component separate from the detector device 10, e.g., connected by connections or signal cables that extend through a wall of a vacuum chamber of the electron beam apparatus via a vacuum feed-through.

In some embodiments, which can be combined with other embodiments described herein, the one or more radially inner detector segments extend from a first radius (R1) to a second radius (R2), and the one or more radially outer detector segments extend from the second radius (R2) to a third radius (R3), as is schematically indicated in FIG. 2. The second radius (R2) may be 6 mm or more and 11 mm or less, e.g., 9 mm or more and 10 mm or less, and/or the third radius may be larger than 12 mm, for example, about 13 mm. The third radius may be larger than 12 mm and smaller than 20 mm. Such a segmentation size enables a reliable detection of the small-angle BSEs and of the large-angle BSEs, and allows the detector device to be operated in different operation modes depending on the landing energy of the primary electron beam, as is explained below in further detail.

In some embodiments, the first radius (R1) may be 500 μm or more and 3 mm or less, e.g., between 1 mm and 2 mm. The first radius (R1) defines the size of the central detector opening and enables the primary electron beam and optionally axial signal electrons to propagate through the electron detector without being negatively affected.

In some implementations, the one or more radially inner detector segments 21 may cover a first surface area, e.g., an essentially annular surface area, and the one or more radially outer detector segments may cover a second surface area, e.g., an essentially annular surface area. A ratio between the second surface area and the first surface area may be from 0.7 to 2, particularly from 0.9 to 1.1. In particular, the first surface area and the second surface area may have essentially the same size. For example, the first surface area may be between 200 mm² and 400 mm², e.g., from 250 mm² to 300 mm², and/or the second surface area may be between 200 mm² and 400 mm², e.g., from 250 mm² to 300 mm². A large second surface area increases the number of large-angle BSEs that can be detected. If the second surface area essentially corresponds in size to the first surface area or is larger in size than the first surface area, the contribution of the large-angle BSEs to the overall detector output signal can be increased. Also, the detector device can be operated in different operation modes, as is explained in further detail below.

In some embodiments, which can be combined with other embodiments described herein, the electron beam apparatus 100 may further include a retarding field device for retarding the primary electron beam before impinging on the sample. The retarding field device can include a proximity electrode 130 with at least one opening allowing a passage of the primary electron beam and of the signal electrons, particularly the first group and the second group of signal electrons. In particular, the primary electron beam may pass through the opening of the proximity electrode 130 in a first direction, and the signal electrons can propagate through the opening(s) of the proximity electrode 130 in an opposite direction. The proximity electrode 130 can be set on an electric potential suitable to decelerate the primary electron beam when hitting the sample. Further, the electric field generated by the proximity electrode 130 can accelerate the signal electrons away from the sample, particularly toward the detector device 10.

A proximity electrode 130 may be understood as the beam influencing electrode closest to the sample or the sample stage. In an example, the distance between the proximity electrode and the sample stage or the sample is smaller than the distance between the objective lens and the sample stage or the sample. According to some embodiments, enabling a detection of large-angle backscattered particles with reduced detection losses is achieved by using the proximity electrode having an opening as an entrance window for the backscattered particle detection.

The proximity electrode can further be used for decelerating the primary charged particle beam as a final component of the retarding field device. The proximity electrode may further be able to control the extraction field strength for the signal electrons.

Since the retarding field device may provide a significant potential difference between sample and column of the electron beam apparatus of typically 5 keV or more, or even 30 keV or more, BSEs passing through the opening of the proximity electrode are accelerated before reaching the detector device 10 which is advantageous for high efficiency detection. The electron detector 120 may optionally act as an acceleration electrode and be set on a respective potential. Accelerating the BSEs is in particular beneficial when detecting backscattered particles at a low landing energy (e.g. of below 10 keV) or when backscattered particles have lost a part of their energy when travelling through the sample material. In the case that the column is on ground potential, detection with semiconductor detectors like pin diodes may be practicable to realize because the detector as well as the detector electronics may be set on a ground potential.

In some embodiments, the detector device 10 can be arranged between the proximity electrode 130 and the objective lens 110, as is schematically depicted in FIG. 1. The proximity electrode can, for example, be used for adjusting a landing energy of the primary electron beam on the sample, e.g., to 35 keV or less, to 25 keV or less, or even 10 keV or less. The landing energy of the primary electron beam on the sample can influence the number of BSEs reflected from the sample. Further, as explained above, the landing energy of the primary electron beam on the sample influences the BSE energy and thereby the number of BSEs impinging on the inner and outer detector segments. Specifically, a higher landing energy of the primary electron beam on the sample generally increases the number of BSEs detectable by the radially outer detector segment(s).

The “maximum detection speed” of an electron detector defines the maximum scanning speed at which a sample can be scanned while the detector is still able to temporally resolve the signal electrons originating from different points (or pixels) of the sample. The “maximum detection speed” of an electron detector can also be referred to as the “detector bandwidth” which constitutes a characteristic parameter of an electron detector. For example, an electron detector with a bandwidth of more than 20 MHz enables a quick scanning speed, while an electron detector with a bandwidth below 1 MHz is not very fast.

The maximum detection speed (or bandwidth) of a detector segment may depend on the amplification strength applied to the signal of the detector segment. Accordingly, a detector segment with a high amplification strength may be operable at a lower bandwidth than a detector segment with a low amplification strength.

According to some embodiments described herein, the one or more radially inner detector segments, being connected to an amplifying circuit with a lower gain, are configured for a first maximum detection speed, and/or the one or more radially outer segments, being connected to an amplifying circuit with a higher gain, are configured for a second maximum detection speed, wherein the first maximum detection speed may be faster than the second maximum detection speed. In other words, the inner detector segments may have a higher bandwidth (i.e., can be operated with a quicker scanning speed) than the outer detector segments. For example, the bandwidth of the one or more radially outer detector segments may be from 5 MHz to 15 MHz, particularly about 10 MHz, and/or the bandwidth of the one or more radially inner detector segments may be 15 MHz or more, particularly faster than 20 MHz, e.g., between 20 MHz and 50 MHz.

In some embodiments, which can be combined with other embodiments described herein, the detector device 10 can be operated in (at least) two operation modes, particularly in a first operation mode, in a second operation mode, and/or in a third operation mode. Each operation mode may be characterized by a respective (maximum) detection speed. In particular, the first and third operation modes May be characterized by a detection speed (or detector bandwidth) slower than the second operation mode. In some embodiments, the detector device 10 can be operated in at least two of the three operation modes (e.g., in the first and second operation modes), or in three operation modes (i.e., in the first, second, and third operation modes).

In the first operation mode, both the first group and the second group of signal electrons are detected with the detector device 10, and the respective detector signals are amplified with the respective amplification strengths G1 and G2. Since the second group of signal electrons is detected with the radially outer detector segments that provide a high amplification strength, but have a lower bandwidth, in the first operation mode, the overall bandwidth of the detector device may be lower than in the second operation mode.

In the second operation mode, the first group of signal electrons is detected with the detector device and the respective detector signals are amplified with the first amplification strength G1, but no second group of signal electrons is detected.

Specifically, only the radially inner detector segment(s) may be operated in the second operation mode, not the radially outer detector segment(s). Since only the first group of signal electrons is detected with the radially inner detector segments that provide a lower amplification strength, but have a higher bandwidth, the overall bandwidth of the detector device (with the radially outer detector segments not being in operation, e.g., switched off) is increased in the second operation mode.

In the third operation mode, the second group of signal electrons is detected with the detector device and the respective detector signals are amplified with the second amplification strength G2, but no first group of signal electrons is detected. Specifically, only the radially outer detector segment(s) may be operated in the third operation mode, not the radially inner detector segment(s). Since only the second group of signal electrons is detected with the radially outer detector segments that provide a higher amplification strength, but have a lower bandwidth, the overall bandwidth of the detector device (with the radially inner detector segments not being in operation, e.g., switched off) may be lower in the third operation mode than in the second operation mode. Specifically, the detector bandwidth of the first operation mode may correspond to the detector bandwidth of the third operation mode (where the slower outer detector segments are operated), and the detector bandwidth of the second operation mode may be higher (since the slower outer detector segments are not operated in the second operation mode).

For example, in the first and third operation modes that detect large-angle BSEs, the detection speed (or bandwidth) may be from 5 MHz to 15 MHz. In the second operation mode that only detects small-angle signal electrons impinging on the radially inner detector segments, the detection speed (or bandwidth) may be higher than 15 MHz, e.g., 25 MHz or more.

The operation mode of the detector device may be selected based on the landing energy of the primary electron beam. For example, if the landing energy is below 15 keV, most of the signal electrons can be detected with the radially inner detector segments. The second operation mode can be applied, in which only the radially inner detector segments are operated that are characterized by a high maximum detection speed. Accordingly, fast BSE detection is possible with the radially inner detector segments.

If the landing energy is above 15 keV, such as, e.g., 30 keV or more, also a considerable number of high-energy BSEs will be released from the sample that can be detected by the radially outer detector segments,. The first operation mode can be applied, in which both the radially inner detector segments and the radially outer detector segments are operated. The first operation mode is characterized by a reduced maximum detection speed, because also the radially outer detector segments are in operation. Accordingly, high amplification at the radially outer detector segments is possible in applications having high-energy BSE output at large emission angles at a low signal strength. The first operation mode may be applied, e.g., at landing energies of the primary electron beam above 15 keV, e.g., 30 keV or more, or even 50 keV or more. Alternatively, the third operation mode can be applied, in which only the large-angle BSEs are detected by the radially outer detector segment(s).

For the radially inner detector segments, where up to a landing energy of 15 keV most of the BSEs are detected, less amplification is sufficient, but a higher bandwidth of, e.g., at least 20 MHz for fast defect detection is beneficial. A high range of defects can be quickly and reliably detected in the second operation mode.

For the radially outer detector segments, where large-angle BSEs at landing energies of 15 keV or higher can be detected, a high amplification due to a small BSE input current is beneficial, so that the large-angle BSEs can still be detected at a reasonable signal-to-noise ratio. Here, the detector bandwidth may be lower, e.g., 10 MHz. Due to the size of the radially outer detector segments, as specified herein, and the high gain applied to the detector signals from the radially outer detector segments, it is possible to detect large-angle BSEs in high landing energy applications. Specific kinds of defects can be inspected.

FIG. 3A shows a detector device 10 with a segmented electron detector as described herein in a schematic perspective view. FIG. 3B shows the detector device of FIG. 3A in a schematic top view. The detector device of FIGS. 3A and 3B essentially corresponds to the detector device of FIG. 2, such that reference can be made to the above explanations, which are not repeated here.

Specifically, the detector device 10 includes the electron detector 120 and the amplifying device 121. The electron detector 120 is an in-lens detector with a central opening 23 for the primary electron beam and with one or more radially inner detector segments 21 and one or more radially outer detector segments 22 surrounding the central opening 23.

The amplifying device 121 is configured to amplify the first detector signals of the one or more radially inner detector segments 21 with the first amplification strength G1 while amplifying the second detector signals of the one or more radially outer detector segments 22 with the second amplification strength G2 higher than the first amplification strength G1.

The amplifying device 121 may be a pre-amplifier that is connected to the electron detector 120. The pre-amplifier is at least one of (i) integrated with the electron detector 120, (ii) arranged directly adjacent to the electron detector 120 inside a vacuum chamber of the electron beam apparatus, and (iii) mounted in a vacuum chamber of the electron beam apparatus.

In the embodiment shown in FIGS. 3A and 3B, the electron detector 120 includes a plurality of radially inner detector segments surrounding the central opening 23 in an annular arrangement, particularly in a four-quadrant arrangement, and a plurality of radially outer detector segments surrounding the plurality of radially inner segments in an annular arrangement, particularly in a four-quadrant arrangement.

In some embodiments, the one or more radially inner detector segments 21 include two or more inner segments, particularly four inner segments, surrounding the central opening in an annular arrangement. Alternatively or additionally, the one or more radially outer detector segments 22 include two or more outer segments, particularly four outer segments, or even eight outer segments, surrounding the central opening in an annular arrangement. As is schematically depicted in FIGS. 3A and 3B, the one or more radially inner detector segments 21 may include four inner segments surrounding the central opening 23 in an annular four-quadrant-configuration, and the one or more radially outer detector segments 22 may include four outer segments surrounding the four inner segments in an annular four-quadrant-configuration.

The electron detector 120 may be a segmented semiconductor detector, such as a PIN diode detector with a segmented detection surface 125, and the amplifying device 121 may be a multi-channel transimpedance amplifier integrated with or arranged adjacent to the segmented semiconductor detector. A first subset of channels of the amplifying device 121 may be configured to apply the first amplification strength and a second subset of channels of the amplifying device may be configured to apply the second amplification strength. Specifically, the four first detector signals provided by the four radially inner detector segments may be amplified with the first amplification strength in four channels of the amplifying device, and the four second detector signals provided by the four radially outer detector segments may be amplified with the second amplification strength in four further channels of the amplifying device. In particular, the multi-channel amplifier may have a first subset of channels connected to the radially inner detector segments and configured for amplification with the first amplification strength and a second subset of channels connected to the radially outer detector segments and configured for amplification with the second amplification strength higher than the first amplification strength.

An (optional) main amplifier 160 may be additionally provided for amplifying the pre-amplified signals provided by the amplifying device 121. The main amplifier 160 may be arranged separately from the detector device 10, e.g., outside the vacuum chamber of the electron beam apparatus.

A double four-quadrant segmented detector, as depicted in FIGS. 3A and 3B, enables a signal electron detection that differentiates according to both the emission angle of the respective signal electron relative to the optical axis (e.g., small-angle BSE vs. large-angle BSE) and the azimuthal angle of the respective signal electron (e.g., via respective segments for top, bottom, right, and left directions). Accordingly, specific defects, surface gradients, surface topographies and geometries, and/or details of buried layers can be inspected and/or imaged. Weak signals at the radially outer segments and stronger signals at the radially inner segments can be reliably detected with an improved signal-to-noise ratio.

According to another aspect, a method of imaging and/or inspecting a sample, particularly with a detector device and/or with an electron beam apparatus according to any of the embodiments described herein, is provided.

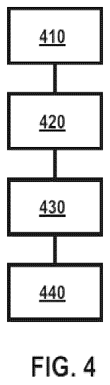

FIG. 4 is a flow diagram that schematically illustrates a method as described herein. In block 410, a primary electron beam is generated that propagates along an optical axis.

In block 420, the primary electron is focused with an objective lens on the sample for causing an emission of signal electrons, wherein the signal electrons include BSEs. In particular, a first group of signal electrons propagates in a first range of radial distances from the optical axis in the plane of the electron detector, and a second group of signal electrons propagates in a second range of radial distances further from the optical axis than the first group. The first and second groups of signal electrons are detected with a detector device that includes an electron detector, particularly a semiconductor detector, as described herein.

In block 430, one or more first detector signals caused by the first group of signal electrons impinging on one or more radially inner detector segments of the electron detector are amplified with a first amplification strength, and one or more second detector signals caused by the second group of signal electrons impinging on one or more radially outer detector segments of the electron detector are amplified with a second amplification strength. The second amplification strength (=second gain) for the outer detector segments is higher than the first amplification strength (=first gain) for the inner detector segments, e.g., by a factor or 2 or more, or 5 or more.

In some embodiments, the one or more first detector signals and the one or more second detector signals are amplified with a pre-amplifier, particularly with at least one transimpedance amplification circuit of the pre-amplifier, more particularly with a multi-channel transimpedance amplifier with two subsets of channels. The pre-amplifier may be at least one of integrated with the electron detector and arranged adjacent to the electron detector in a vacuum environment.

In some embodiments, which can be combined with other embodiments described herein, the one or more radially inner detector segments include two or four inner detector segments that surround a central opening of the electron detector in an annular arrangement, and/or the one or more radially outer detector segments include two or four outer detector segments that surround the two or four inner detector segments in an annular arrangement. Each detector segment may have the shape of a ring segment, extending around the central opening by an angle of, e.g., 180° or 90°, respectively.

The landing energy of the primary electron beam impinging on the sample may be 15 keV or more, particularly 30 keV or more, more particularly 35 keV or more, or even 50 keV or more. A higher landing energy increases the number of high-energy BSEs reflected from the sample that propagate more distant from the optical axis, if reflected off-axially. At landing energies of, e.g., 10 keV or less, only a negligible number of BSEs may impinge on the radially outer detector segments. Accordingly, methods described herein are particularly beneficial, if the landing energy of the primary electron beam is higher than 15 keV. The large-angle BSEs generated at high landing energies can be detected with a good signal-to-noise ratio according to the methods described herein.

In some embodiments, the detector device can be operated at least in a first operation mode and in a second operation mode. In the first operation mode, both the first group and the second group of signal electrons are detected, and the respective detector signals are amplified with different amplification strengths, as is schematically depicted in block 430. In the first operation mode, the primary electron beam may impinge on the sample with a first landing energy, wherein the first landing energy may be, e.g. 15 keV or more, such that also large-angle BSEs having high particle energies are emitted from the sample.

In (optional) box 440, the method further includes switching from the first operation mode to a second operation mode or to a third operation mode of the detector device. In the second operation mode, the first group of signal electrons is detected, but no second group of signal electrons is detected. For example, only the one or more inner detector segments are operated in the second operation mode, but not the one or more outer detector segments. In the second operation mode, the primary electron beam may impinge on the sample with a second landing energy smaller than the first landing energy, particularly wherein the second landing energy may be, e.g., 10 keV or less, such that no substantial number of large-angle BSEs is emitted from the sample. In the optional third operation mode, the second group of signal electrons is detected, but no first group of signal electrons is detected. For example, the radially inner detector segments are not operated or are switched off.

The first operation mode may be characterized by a second (maximum) detection speed (or detector bandwidth), and the second operation mode may be characterized by a first (maximum) detection speed (or detector bandwidth) faster than the second (maximum) detection speed. In other words, when, in the first operation mode, all the detector segments are operated, the sample can be scanned with a slower maximum speed as compared to the second operation mode, in which only the radially inner detector segments are operated.

In particular, the following embodiments are described herein:

Embodiment 1. A detector device (10) for detecting signal electrons, comprising: an electron detector (120) with a central opening (23) for a passage of a primary electron beam (105), one or more radially inner detector segments that at least partially surround the central opening, and one or more radially outer detector segments that at least partially surround the central opening. The detector device is configured to amplify one or more first detector signals caused by a first group of signal electrons impinging on the one or more radially inner detector segments with a first amplification strength while amplifying one or more second detector signals caused by a second group of signal electrons impinging on the one or more radially outer detector segments with a second amplification strength higher than the first amplification strength.

Embodiment 2. The detector device of embodiment 1, further comprising an amplifying device with one or more first amplification circuits connected to the one or more radially inner detector segments and configured to amplify the one or more first detector signals with the first amplification strength. The amplifying device further has one or more second amplification circuits connected to the one or more radially outer detector segments and configured to amplify the one or more second detector signals with the second amplification strength.

Embodiment 3. The detector device of embodiment 2, wherein the one or more first amplification circuits and the one or more second amplification circuits are transimpedance amplification circuits or belong to transimpedance amplification circuits.

Embodiment 4. The detector device of embodiment 2 or 3, wherein the amplifying device is a pre-amplifier connected to the electron detector, particularly wherein the pre-amplifier is at least one of integrated with the electron detector and arranged directly adjacent to the electron detector, particularly in a vacuum chamber of an electron beam apparatus.

Embodiment 5. The detector device of any of embodiments 1 to 4, wherein the first amplification strength and the second amplification strength are invariable. In particular, the detector device does not allow the gain to be varied or switched.

Embodiment 6. The detector device of any of embodiments 1 to 5, wherein the second amplification strength is higher than the first amplification strength by a factor of 2 or more, particularly 3 or more, or even 5 or more.

Embodiment 7. The detector device of any of embodiments 1 to 6, wherein the one or more radially inner detector segments cover a first surface area of the electron detector and the one or more radially outer detector segments cover a second surface area of the electron detector, a ratio between the second surface area and the first surface area being from 0.7 to 2, particularly from 0.9 to 1.1. In particular, the one or more radially inner detector segments cover a first area of 200 mm² or more and 400 mm² or less, particularly from 250 mm² to 300 mm², and/or the one or more radially outer detector segments cover a second area of 200 mm² or more and 400 mm² or less, particularly from 250 mm² to 300 mm².

Embodiment 8. The detector device of any of embodiments 1 to 7, wherein the one or more radially inner detector segments extend from a first radius (R1) to a second radius (R2), and the one or more radially outer detector segments extend from the second radius (R2) to a third radius (R3), particularly respectively in an annular arrangement, wherein the second radius (R2) is between 7 mm and 11 mm, and the third radius (R3) is larger than 12 mm. Optionally, the first radius (R1) may be 500 μm or more and 2 mm or less, and/or the third radius (R3) may be 12 mm or more and 20 mm or less.

Embodiment 9. The detector device of any of embodiments 1 to 8, wherein the one or more radially inner detector segments comprise two or more inner segments surrounding the central opening in an annular arrangement, and/or the one or more radially outer detector segments comprise two or more outer segments surrounding the central opening in an annular arrangement.

Embodiment 10. The detector device of any of embodiments 1 to 9, wherein the one or more radially inner detector segments comprise four inner segments surrounding the central opening in an annular, four-quadrant-configuration, and the one or more radially outer detector segments comprises four outer segments surrounding the four inner segments in an annular, four-quadrant-configuration.

Embodiment 11. The detector device of any of embodiments 1 to 10, wherein the electron detector is a segmented semiconductor detector, particularly a PIN diode detector, connected to a multi-channel transimpedance amplifier, with a first subset of channels configured to apply the first amplification strength and a second subset of channels configured to apply the second amplification strength. The multi-channel transimpedance amplifier may be integrated with or arranged directly adjacent to the segmented semiconductor detector, e.g., in a common detector housing and/or integrated on the same chip.

Embodiment 12. The detector device of any of embodiments 1 to 11, wherein the one or more radially inner detector segments are configured for a first maximum detection speed and the one or more radially outer detector segments are configured for a second maximum detection speed, the first maximum detection speed being faster than the second maximum detection speed.

Embodiment 13. The detector device of any of embodiments 1 to 12, wherein the detector device can be operated in at least two different operation modes. In a first operation mode, both the first group and the second group of signal electrons are detected with the detector device with a second detection speed. In a second operation mode, the first group of signal electrons is detected with the detector device with a first detection speed faster than the second detection speed, but no second group of signal electrons is detected. In some embodiments, the second (=slower) detection speed corresponds to the maximum detection speed of the one or more radially outer detector segments, and/or the first (=faster) detection speed corresponds to the maximum detection speed of the one or more radially inner detector segment. In some embodiments, the first or second operation mode is selected based on a landing energy of the primary electron beam on the sample. Specifically, the first operation mode may be selected for a first range of landing energies of the primary electron beam, and the second operation mode may be selected for a second range of landing energies of the primary electron beam lower than the first range. Specifically, the first operation mode may be characterized by a slow (maximum) detection speed and by a detection of both the first group and the second group of signal electrons, and the second detection mode may be characterized by a fast (maximum) detection speed and by a detection of the first group, but not the second group of signal electrons. In an optional third operation mode, the second group of signal electrons is detected by the detector device with the second (slower) detection speed, but no first group of signal electrons is detected.

Embodiment 14. An electron beam apparatus, comprising: an electron source for generating a primary electron beam propagating along an optical axis; a sample stage for supporting a sample; an objective lens configured to focus the primary electron beam on the sample for releasing signal electrons from the sample; and a detector device, comprising: an electron detector (120) comprising a central opening (23) for the primary electron beam, one or more radially inner detector segments (21) that at least partially surround the central opening, and one or more radially outer detector segments (22) that at least partially surround the central opening. The detector device is configured to amplify one or more first detector signals caused by a first group of signal electrons impinging on the one or more radially inner detector segments (21) with a first amplification strength, while amplifying one or more second detector signals caused by a second group of signal electrons impinging on the one or more radially outer detector segments (22) with a second amplification strength higher than the first amplification strength.

Embodiment 15. The electron beam apparatus of embodiment 14, wherein the one or more first detector signals and the one or more second detector signals are amplified with a pre-amplifier of the detector device that is connected to the electron detector and is at least one of (i) integrated with the electron detector, (ii) arranged directly adjacent to the electron detector inside a vacuum chamber of the electron beam apparatus, and (iii) mounted in a vacuum chamber of the electron beam apparatus.

Embodiment 16. The electron beam apparatus of embodiment 14 or 15, further comprising a main amplifier for amplifying pre-amplified detector signals provided by the pre-amplifier.

Embodiment 17. The electron beam apparatus of any of embodiments 14 to 16, further comprising a retarding field device for retarding the primary electron beam before impinging on the sample. The retarding field device may include a proximity electrode with an opening allowing a passage of the primary electron beam and of the first group and the second group of signal electrons. Optionally, the detector device may be arranged between the proximity electrode and the objective lens. In some embodiments, a landing energy of the primary electron beam on the sample can be varied with the retarding field device, for example, in a range from 50 keV or 35 keV down to, e.g., 10 keV or less.

Embodiment 18. A method of imaging and/or inspecting a sample, comprising: generating a primary electron beam propagating along an optical axis; focusing, with an objective lens, the primary electron beam on the sample for causing an emission of a first group of signal electrons and of a second group of signal electrons, the second group of signal electrons propagating at distances further away from the optical axis than the first group of signal electrons in the plane of an electron detector; amplifying one or more first detector signals caused by the first group of signal electrons impinging on one or more radially inner detector segments of the electron detector with a first amplification strength; and amplifying one or more second detector signals caused by the second group of signal electrons impinging on one or more radially outer detector segments of the electron detector with a second amplification strength higher than the first amplification strength.

Embodiment 19. The method of embodiment 18, wherein the one or more first detector signals and the one or more second detector signals are amplified with a pre-amplifier, particularly with transimpedance amplification circuits of the pre-amplifier, the pre-amplifier being integrated with the electron detector or arranged adjacent to the electron detector in a vacuum environment.

Embodiment 20. The method of embodiment 18 or 19, wherein the one or more radially inner detector segments comprise two or four inner detector segments that surround a central opening in the electron detector in an annular arrangement, and the one or more radially outer detector segments comprise two or four outer detector segments that surround the two or four inner detector segments in an annular arrangement, the method comprising: amplifying two or four first detector signals provided by the two or four inner detector segments with the first amplification strength, and amplifying two or four second detector signals provided by the two or four outer detector segments with the second amplification strength.

Embodiment 21. The method of any of embodiments 18 to 20, wherein a landing energy of the primary electron beam on the sample is 20 keV or more, particularly 30 keV or more, more particularly 35 keV or more.

Embodiment 22. The method of any of embodiments 17 to 19, further comprising switching between a first operation mode and a second operation mode (or optionally a third operation mode), wherein, in the first operation mode, the primary electron beam impinges on the sample with a first landing energy, and both the first group and the second group of signal electrons are detected; and in the second operation mode, the primary beam impinges on the sample with a second landing energy smaller than the first landing energy, and the first group of signal electrons is detected, but no second group of signal electrons is detected. In the second operation mode, the sample may be scanned with a first (fast) scanning speed and the first group of signal electrons may be detected with a first (fast) detection speed. In the first operation mode, the sample may be scanned with a second (slow) scanning speed and the first and second groups of signal electrons may be detected with a second (slow) detection speed. The first detection speed is faster than the second detection speed. The first detection mode and the second detection mode may be selected depending on a landing energy of the primary electron beam.

Embodiment 23. A detector device for detecting signal electrons, comprising: an electron detector with a central opening for a passage of a primary electron beam, one or more radially inner detector segments that at least partially surround the central opening, and one or more radially outer detector segments that at least partially surround the central opening. The detector device further includes an amplifying device configured to amplify one or more first detector signals of the one or more radially inner detector segments with a first amplification strength, while amplifying one or more second detector signals of the one or more radially outer detector segments with a second amplification strength higher than the first amplification strength.

While the foregoing is directed to embodiments, other and further embodiments may be devised without departing from the basic scope, and the scope thereof is determined by the claims that follow.

What is claimed:

1. A detector device for detecting signal electrons, comprising:
an electron detector, comprising
a central opening for a passage of a primary electron beam;
one or more radially inner detector segments that at least partially surround the central opening; and
one or more radially outer detector segments that at least partially surround the central opening,
wherein the detector device is configured to amplify one or more first detector signals caused by a first group of signal electrons impinging on the one or more radially inner detector segments with a first amplification strength while amplifying one or more second detector signals caused by a second group of signal electrons impinging on the one or more radially outer detector segments with a second amplification strength higher than the first amplification strength.

2. The detector device of claim 1, comprising an amplifying device with one or more first amplification circuits connected to the one or more radially inner detector segments and configured to amplify the one or more first detector signals with the first amplification strength and with one or more second amplification circuits connected to the one or more radially outer detector segments and configured to amplify the one or more second detector signals with the second amplification strength.

3. The detector device of claim 2, wherein the one or more first amplification circuits and the one or more second amplification circuits are transimpedance amplification circuits.

4. The detector device of claim 2, wherein the amplifying device is a pre-amplifier connected to the electron detector, wherein the pre-amplifier is at least one of integrated with the electron detector and arranged adjacent to the electron detector.

5. The detector device according to claim 1, wherein the first amplification strength and the second amplification strength are invariable.

6. The detector device according to claim 1, wherein the second amplification strength is higher than the first amplification strength by a factor of 2 or more.

7. The detector device of claim 1, wherein the one or more radially inner detector segments cover a first surface area and the one or more radially outer detector segments cover a second surface area, a ratio between the second surface area and the first surface area being from 0.7 to 2.

8. The detector device of claim 1, wherein the one or more radially inner detector segments extend from a first radius to a second radius, and the one or more radially outer detector segments extend from the second radius to a third radius, wherein the second radius is between 7 mm and 11 mm, and the third radius 15 is larger than 12 mm.

9. The detector device of claim 1, wherein the one or more radially inner detector segments comprise two or more inner segments surrounding the central opening in an annular arrangement, and the one or more radially outer detector segments comprise two or more outer segments surrounding the central opening in an annular arrangement.

10. The detector device of claim 1, wherein the one or more radially inner detector segments comprise four inner segments surrounding the central opening in an annular four-quadrant-configuration, and the one or more radially outer detector segments comprises four outer segments surrounding the four inner segments in an annular four-quadrant-configuration.

11. The detector device of claim 1, wherein the electron detector is a segmented semiconductor detector connected to a multi-channel transimpedance amplifier integrated with or arranged adjacent to the segmented semiconductor detector, with a first subset of channels configured to apply the first amplification strength and a second subset of channels configured to apply the second amplification strength.

12. The detector device of claim 1, wherein the one or more radially inner detector segments are configured for a first maximum detection speed and the one or more radially outer detector segments are configured for a second maximum detection speed, the first maximum detection speed being faster than the second maximum detection speed.

13. The detector device according to claim 1, wherein the detector device can be operated in at least two of the following operation modes:
in a first operation mode, in which both the first group and the second group of signal electrons are detected with the detector device with a second detection speed,
in a second operation mode, in which the first group of signal electrons is detected with the detector device with a first detection speed faster than the second detection speed, and the second group of signal electrons is not detected, and
in an optional third operation mode, in which the second group of signal electrons is detected with the detector device with the second detection speed, and the first group of signal electrons is not detected.

14. An electron beam apparatus, comprising:
an electron source for generating a primary electron beam propagating along an optical axis;
a sample stage for supporting a sample;
an objective lens configured to focus the primary electron beam on the sample for releasing signal electrons; and
a detector device, comprising:
an electron detector comprising a central opening for the primary electron beam, one or more radially inner detector segments that at least partially surround the central opening, and one or more radially outer detector segments that at least partially surround the central opening,
wherein the detector device is configured to amplify one or more first detector signals caused by a first group of signal electrons impinging on the one or more radially inner detector segments with a first amplification strength while amplifying one or more second detector signals caused by a second group of signal electrons impinging on the one or more radially outer detector segments with a second amplification strength higher than the first amplification strength.

15. The electron beam apparatus according to claim 14, wherein the one or more first detector signals and the one or more second detector signals are amplified with a pre-amplifier of the detector device that is connected to the electron detector and is at least one of (i) integrated with the electron detector, (ii) arranged directly adjacent to the electron detector inside a vacuum chamber of the electron beam apparatus, and (iii) fixedly mounted in a vacuum chamber of the electron beam apparatus.

16. The electron beam apparatus according to claim 15, further comprising a main amplifier for amplifying pre-amplified detector signals provided by the pre-amplifier.

17. A method of imaging and/or inspecting a sample, comprising:
generating a primary electron beam propagating along an optical axis;
focusing, with an objective lens, the primary electron beam on the sample for causing an emission of a first group of signal electrons and of a second group of signal electrons, the second group propagating further from the optical axis than the first group;
amplifying one or more first detector signals caused by the first group of signal electrons impinging on one or more radially inner detector segments of an electron detector with a first amplification strength; and
amplifying one or more second detector signals caused by the second group of signal electrons impinging on one or more radially outer detector segments of the electron detector with a second amplification strength higher than the first amplification strength.

18. The method of claim 17, wherein the one or more first detector signals and the one or more second detector signals are amplified with a pre-amplifier, particularly with at least one transimpedance amplification circuit of the pre-amplifier, the pre-amplifier being at least one of integrated with the electron detector and arranged adjacent to the electron detector in a vacuum environment.

19. The method of claim 17, wherein the one or more radially inner detector segments comprise two or four inner detector segments that surround a central opening in the electron detector in an annular arrangement, and the one or more radially outer detector segments comprise two, four, or eight outer detector segments that surround the two or four inner detector segments in an annular arrangement, the method comprising:
amplifying two or four first detector signals provided by the two or four inner detector segments with the first amplification strength, and
amplifying two or four second detector signals provided by the two or four outer detector segments with the second amplification strength.

20. The method of claim 17, wherein a landing energy of the primary electron beam on the sample is 15 keV or more.

21. The method of claim 17, further comprising switching between a first operation mode and at least one of a second operation mode and a third operation mode,
wherein, in the first operation mode, the primary electron beam impinges on the sample with a first landing energy, and both the first group and the second group of signal electrons are detected;
in the second operation mode, the primary beam impinges on the sample with a second landing energy smaller than the first landing energy, and the first group of signal electrons is detected, but not the second group of signal electrons; and
in the third operation mode, the second group of signal electrons is detected, but not the first group of signal electrons.
